(19) United States
(12) Patent Application Publication
(10) Pub. No.: US 2026/0001804 A1
(43) Pub. Date: Jan. 1, 2026

(54) MANUFACTURING METHOD OF WINDOW GLASS

(71) Applicant: Samsung Display Co., LTD., Yongin-si (KR)

(72) Inventor: YONG-KYUN SIM, Yongin-si (KR)

(21) Appl. No.: 19/187,412

(22) Filed: Apr. 23, 2025

(30) Foreign Application Priority Data
Jun. 28, 2024 (KR) 10-2024-0085326

(51) Int. Cl. C03C 15/00; C03C 27/10; H05K 5/03

(52) U.S. Cl. CPC C03C 15/00; C03C 27/10; H05K 5/03

(57) ABSTRACT

A manufacturing method of a window glass includes forming a stack structure in which a resin is applied between mother glasses, curing a portion of the applied resin by irradiating the stack structure with rays, forming groove patterns on the mother glasses by dipping the stack structure including the cured resin into an etching solution, and cutting the stack structure.

This application claims priority to Korean Patent Application No. 10-2024-0085326, filed on Jun. 28, 2024, and all the benefits accruing therefrom under 35 U.S.C. § 119, the content of which in its entirety is herein incorporated by reference.

### BACKGROUND

### (1) Field

The disclosure herein relates to a manufacturing method of a window glass, and more particularly, to a manufacturing method of a window glass included in a foldable electronic device.

### (2) Description of the Related Art

Various electronic devices such as a television, a mobile phone, a tablet computer, and a game console are being developed. Recently, flexible electronic devices including a flexible display panel, which is slidable or foldable, are being developed.

A component included in a flexible electronic device may be desired to be appropriately designed to achieve a folding characteristic of the electronic device. Accordingly, it is desired for a window included in a flexible electronic device to have an improved folding characteristic in a folding region.

### SUMMARY

The disclosure provides a manufacturing method of a window glass, through which a plurality of sheets of a window glass are efficiently produced.

The disclosure also provides a manufacturing method of a window glass having improved reliability by etching the window glass in both directions.

An embodiment of the invention provides a manufacturing method of a window glass including: forming a stack structure in which a resin is applied between mother glasses; curing a portion of the applied resin by irradiating the stack structure with rays; forming groove patterns on the mother glasses by dipping the stack structure including the cured resin into an etching solution; and cutting the stack structure.

In an embodiment, the forming the groove patterns may include: forming an upper groove by etching an upper surface of each of the mother glasses; and forming a lower groove by etching a lower surface of each of the mother glasses, where the forming the upper groove and forming the lower groove may be simultaneously performed.

In an embodiment, the resin may include a photosensitive material, the rays may include ultraviolet rays, and the forming the stack structure may include applying a resin on an upper surface of a mother glass disposed on an uppermost part and a lower surface of a mother glass disposed on a lowermost part in the stack structure.

In an embodiment, an upper groove and a lower groove may be defined in each of the mother glasses on which the forming of the groove patterns is performed, and the upper groove may overlap the lower groove in a plan view.

In an embodiment, a ratio of a depth of the upper groove to a depth of the lower groove may be in a range of about 0.95 to about 1.05 in each of the mother glasses.

In an embodiment, a sum of a depth of the upper groove, a depth of the lower groove, and a thickness of a mother glass overlapping the groove patterns may be the same as a maximum thickness of the mother glass.

In an embodiment, a thickness of a portion of a mother glass overlapping the groove patterns may be smaller than a thickness of another portion of the mother glass not overlapping the groove patterns.

In an embodiment, the curing the portion of the resin may include disposing a mask having a mask pattern formed therein on at least one surface of the stack structure, and irradiating the mask with rays.

In an embodiment, a number of the mother glasses in the stack structure may be greater than or equal to 2 and less than or equal to 30.

In an embodiment, before the forming the groove patterns, the mother glasses may each have a thickness of about 30 micrometers (μm) to about 1000 μm.

In such an embodiment, after the forming the groove patterns, a portion of each of the mother glasses overlapping the groove patterns may each have a thickness of about 30 μm to about 100 μm, and a thickness of the portion of each of the mother glasses overlapping the groove patterns may be smaller than a thickness of another portion of each of the mother glasses not overlapping the groove patterns.

In an embodiment, the mother glass may have a rectangular shape having a horizontal length of about 200 millimeters (mm) to about 700 mm and a vertical length of about 300 mm to about 1000 mm in a plan view.

In an embodiment, a portion of the cured resin may have a reduced volume, such that a gap may be formed between the portion of the cured resin and the mother glass.

In an embodiment, in the forming the groove patterns, the etching solution may flow into the stack structure via the gap.

In an embodiment, the forming the groove patterns may include performing slimming etching.

In an embodiment, in the forming the groove patterns, a speed of etching the mother glass may be in a range of about 0.2 micrometer per minute (μm/min) to about 5 μm/min.

In an embodiment, the method may further include removing the resin from the cut stack structure.

In an embodiment, about 6 sheets to about 30 sheets of a window glass may be formed from each of the mother glasses.

In an embodiment of the invention, a manufacturing method of a window glass includes: forming a stack structure in which a resin is applied between mother glasses; forming a gap between the applied resin and the mother glasses by disposing a mask on one surface of the stack structure and irradiating the mask with rays; dipping the stack structure into an etching solution; and cutting the stack structure.

In an embodiment, the resin may include a photosensitive material, and the rays may include ultraviolet rays.

In an embodiment, the dipping the stack structure into the etching solution may include: allowing the etching solution to flow into the stack structure via the gap; and etching the mother glasses with the etching solution flowing into the stack structure.

In an embodiment, the etching the mother glasses may include: etching an upper surface of each of the mother glasses; and etching a lower surface of each of the mother glasses.

In an embodiment, the etching the upper surface of each of the mother glasses, and the etching the lower surface each of the mother glasses may be simultaneously performed.

In an embodiment, a number of the mother glasses in the stack structure is greater than or equal to 2 and less than or equal to 30.

### BRIEF DESCRIPTION OF THE DRAWINGS

The above and other features of embodiments of the invention will become more apparent by describing in further detail embodiments thereof with reference to the accompanying drawings, in which:

FIG. 1A is a perspective view illustrating an electronic device according to an embodiment;

FIG. 1B is a perspective view illustrating a folding operation of an electronic device according to an embodiment;

FIG. 1C is a plan view illustrating an electronic device according to an embodiment in a folded state;

FIG. 1D is a perspective view illustrating a folding operation of an electronic device according to an embodiment;

FIGS. 2A to 2C are perspective views illustrating an electronic device according to an embodiment;

FIG. 3 is an exploded perspective view illustrating an electronic device according to an embodiment;

FIG. 4 is a cross-sectional view, of a display module, illustrating a portion taken along line I-I′ of FIG. 3;

FIG. 5 is a perspective view illustrating a window glass manufactured through a manufacturing method of a window glass according to an embodiment;

FIG. 6 is a cross-sectional view, of a window glass, illustrating a portion taken along line II-II' of FIG. 5;

FIG. 7A is a block diagram showing a manufacturing method of a window glass according to an embodiment;

FIG. 7B is a block diagram showing a manufacturing method of a window glass according to an embodiment;

FIGS. 8 to 12 are views illustrating processes in a manufacturing method of a window glass according to an embodiment of the invention;

FIG. 13 is an enlarged view of a part of a stack structure formed through a manufacturing method of a window glass according to another embodiment of the invention; and

FIG. 14 is a perspective view illustrating a mother glass manufactured according to another embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In this specification, it will be understood that when an element (or region, layer, portion, or the like) is referred to as being “connected to” or “coupled to” another element, it may be directly connected/coupled to another element, or intervening elements may be disposed therebetween.

Like reference numerals or symbols refer to like elements throughout. Also, in the drawings, the thickness, the ratio, and the dimension of the elements are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

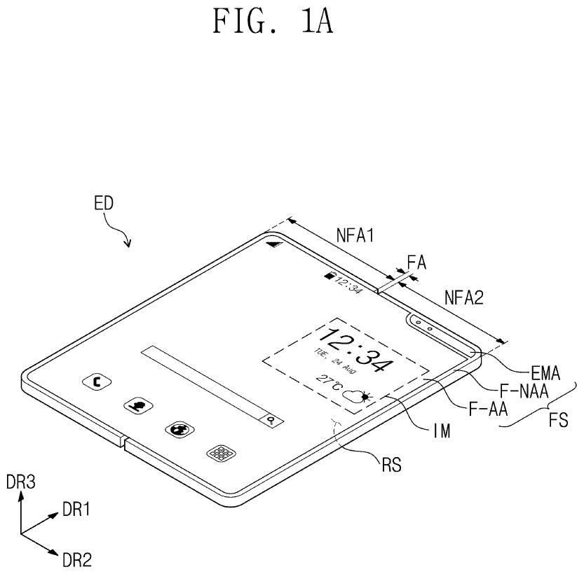

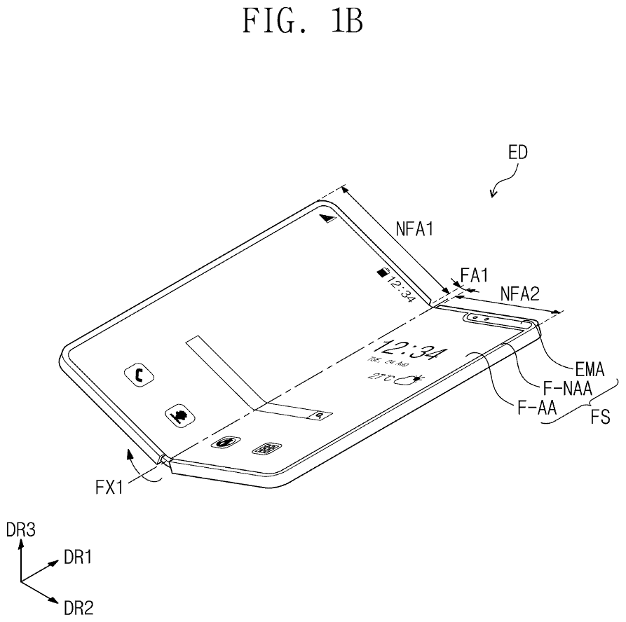

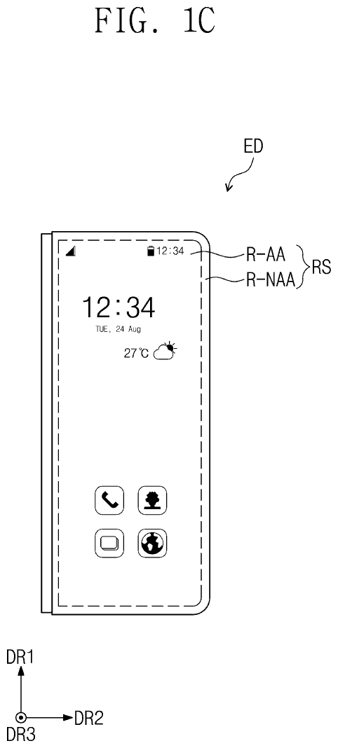

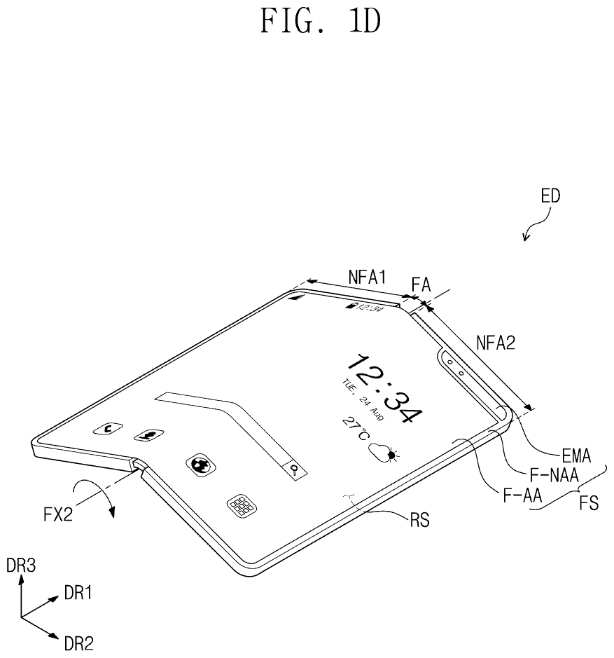

FIG. 1A is a perspective view illustrating an electronic device according to an embodiment.

FIG. 1A is a perspective view illustrating an electronic device ED according to an embodiment in an unfolded state. The electronic device ED according to an embodiment may be activated in response to an electrical signal. In an embodiment, for example, the electronic device ED may be a mobile phone, a tablet computer, a car navigation system, a game console, or a wearable device, but an embodiment of the invention is not limited thereto. FIG. 1A illustrates an embodiment where the electronic device ED is a foldable electronic device. The foldable electronic device ED according to an embodiment may be a mobile phone.

The electronic device ED may include a first display surface FS which is defined by a first direction DR1 and a second direction DR2 crossing the first direction DR1. The electronic device ED may provide an image IM to a user through the first display surface FS. The electronic device ED may display the image IM, in a third direction DR3, on the first display surface FS parallel to each of the first direction DR1 and the second direction DR2.

In the disclosure, the first direction DR1 and the second direction DR2 may be orthogonal to each other, and the third direction DR3 may be a normal direction of a plane defined by the first direction DR1 and the second direction DR2. A thickness direction of the electronic device ED may be a direction parallel to the third direction DR3. A front surface (or an upper surface) and a rear surface (or a lower surface) may be opposed to each other in the third direction DR3, and a normal direction of each of the front surface (or the upper surface) and the rear surface (or the lower surface) may be parallel to the third direction DR3.

The front surface (or the upper surface) is referred to as a surface close to the first display surface FS, and the rear surface (or the lower surface) is referred to as a surface spaced apart from the first display surface FS. Additionally, the rear surface (or the lower surface) is referred to as a surface close to a second display surface RS. The front surface (or the upper surface) is referred to as a direction of getting closer to the first display surface FS, and the rear surface (or the lower surface) is referred to as a direction of getting farther away from the first display surface FS.

A cross section of components is referred to as a surface parallel to the third direction DR3, which is a thickness direction, and a plane is referred to a plane perpendicular to the third direction DR3. The plane is referred to as a plane defined by the first direction DR1 and the second direction DR2.

The electronic device ED may sense an external input applied from the outside. The external input may include various types of inputs applied from the outside of the electronic device ED. In an embodiment, for example, the external input may include not only a touch by a part of a user's body such as user's hands but also an external input (for example, hovering) applied while approaching or being adjacent within a predetermined distance to the electronic device ED. Additionally, the external input may have various forms such as force, pressure, temperature, light, and the like.

The electronic device ED may include the first display surface FS and the second display surface RS. The first display surface FS may include a first active region F-AA, a first peripheral region F-NAA, and an electronic module region EMA. The second display surface RS may be defined as a surface opposed to at least a portion of the first display surface FS. That is, the second display surface RS may be defined as a portion of a rear surface of the electronic device ED.

The first active region F-AA may be activated in response to an electrical signal. The first active region F-AA may be a region in which the image IM may be displayed and various types of external inputs may be detected.

The first peripheral region F-NAA may be a region in which the image IM is not displayed. The first peripheral region F-NAA may be adjacent to the first active region F-AA. The first peripheral region F-NAA may have a predetermined color. The first peripheral region F-NAA may surround the first active region F-AA in a plan view or when viewed in the third direction DR3. Accordingly, a shape of the first active region F-AA may be substantially defined by the first peripheral region F-NAA. However, this is merely illustrated as an example, and the first peripheral region F-NAA may be disposed adjacent to only one side of the first active region F-AA or omitted.

Various electronic modules may be disposed in the electronic module region EMA. In an embodiment, for example, the electronic module may include at least one of a camera, a speaker, a light detection sensor, or a heat detection sensor. The electronic module region EMA may sense an external object received via the first and second display surfaces FS and RS, or provide a sound signal, such as voice, to the outside via the first and second display surfaces FS and RS. The electronic module may include a plurality of components, and are not limited to any one embodiment.

In an embodiment, the electronic module region EMA may be surrounded by the first peripheral region F-NAA. However, this is presented as an example, and an embodiment of the invention is not limited thereto. In another embodiment, for example, the electronic module region EMA may be surrounded by the first active region F-AA and the first peripheral region F-NAA, and the electronic module region EMA may be disposed within the first active region F-AA.

The electronic device ED according to an embodiment may be divided into at least one folding region FA, and a plurality of non-folding regions NFA1 and NFA2 extending from the folding region FA. In an embodiment, for example, a first non-folding region NFA1, the folding region FA, a second non-folding region NFA2 may be defined along the second direction DR2. The electronic device ED may be divided into the first non-folding region NFA1 and the second non-folding region NFA2 which are spaced apart from each other in the second direction DR2 with the folding region FA therebetween. In an embodiment, for example, the first non-folding region NFA1 may be disposed on one side of the folding region FA in the second direction DR2, and the second non-folding region NFA2 may be disposed on the other side of the folding region FA in the second direction DR2.

FIG. 1A illustrates an embodiment in which the electronic device ED includes a single folding region FA, but the embodiment of the invention is not limited thereto. In another embodiment, a plurality of folding regions may be defined in the electronic device ED. In an embodiment, for example, the electronic device according to an embodiment may include two or more folding regions, and three or more non-folding regions disposed with each of the folding regions therebetween.

FIG. 1B is a perspective view illustrating a folding operation of the electronic device ED according to an embodiment. FIG. 1C is a plan view illustrating the electronic device ED according to an embodiment in a folded state. FIG. 1D is a perspective view illustrating a folding operation of the electronic device ED according to an embodiment.

Referring to FIG. 1B, the electronic device ED according to an embodiment may be folded with respect to a first folding axis FX1 extending in the first direction DR1. In a state in which the electronic device ED is folded, the folding region FA may have a predetermined curvature and a radius of a curvature. The electronic device ED may be folded with respect to the first folding axis FX1 and be changed into an in-folded state such that the first non-folding region NFA1 and the second non-folding region NFA2 face each other and the first display surface FS is not exposed to the outside.

Referring to FIG. 1C, in a state in which the electronic device ED according to an embodiment is in-folded, the second display surface RS may be visible to a user. In such an embodiment, the second display surface RS may include a second active region R-AA which displays an image. The second active region R-AA may be activated in response to an electrical signal. The second active region R-AA may be a region in which an image may be displayed and various types of external inputs may be detected.

Additionally, the second display surface RS may include a second peripheral region R-NAA. The second peripheral region R-NAA may be adjacent to the second active region R-AA. The second peripheral region R-NAA may have a predetermined color. The second peripheral region R-NAA may surround the second active region R-AA. In an embodiment, although not illustrated, the electronic device ED may further include, also in the second display surface RS, an electronic module region in which electronic modules including various components are disposed, and is not limited to any one embodiment.

According to an embodiment, in a stated in which the electronic device ED is in-folded, a distance between the first non-folding region NFA1 and the second non-folding region NFA2 may be smaller than a radius of circle defined by a radius of a curvature of the folding region FA. In this state, the folding region FA may be folded in a dumbbell-like shape, and the distance between the first non-folding region NFA1 and the second non-folding region NFA2 may become even shorter. Therefore, it is possible to provide a slimmer electronic device ED in a folded state.

Referring to FIG. 1D, the electronic device ED according to an embodiment may be folded with respect to a second folding axis FX2 extending in the first direction DR1. The electronic device ED may be folded with respect to the second folding axis FX2, and be changed into an out-folded state such that the first display surface FS is exposed to the outside. In an embodiment, the electronic device ED may be configured so as to repeatedly perform an in-folding or out-folding operation from an unfolding operation and vice versa, but an embodiment of the invention is not limited thereto.

FIGS. 1A to 1D illustrate embodiments where the electronic device ED is folded with respect to a single folding axis (FX1 or FX2), but the number of folding axes and the number of non-folding regions corresponding to the number of folding axes are not particularly limited thereto. In another embodiment, for example, the electronic device ED may be folded with respect to a plurality of folding axes such that respective portions of the first display surface FS and the second display surface RS face each other. Also, FIGS. 1A to 1D illustrate embodiments where the first and second folding axes FX1 and FX2 are parallel to a long side of the electronic device ED, but an embodiment of the invention is not limited thereto. In another embodiment, the first and second folding axes FX1 and FX2 may be parallel to a short side of the electronic device ED.

In a state in which the electronic device ED is folded as illustrated in FIG. 1D, the first non-folding region NFA1 and the second non-folding region NFA2 may be defined as portions having the display surfaces FS and RS parallel to a plane defined by the first direction DR1 and the second direction DR2, and the folding region FA may be defined as a region between the first non-folding region NFA1 and the second non-folding region NFA2. The folding region FA may include a curved portion which is curved so as to have a predetermined curvature in a folded state.

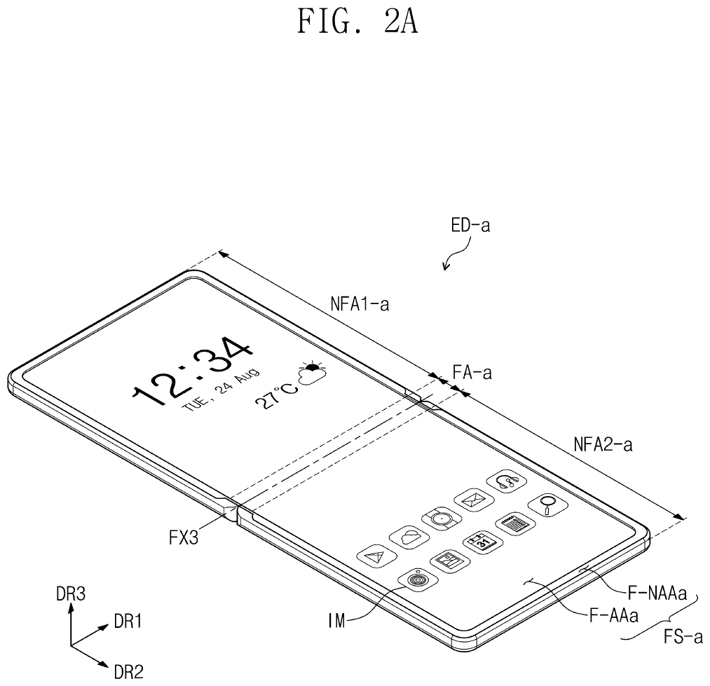

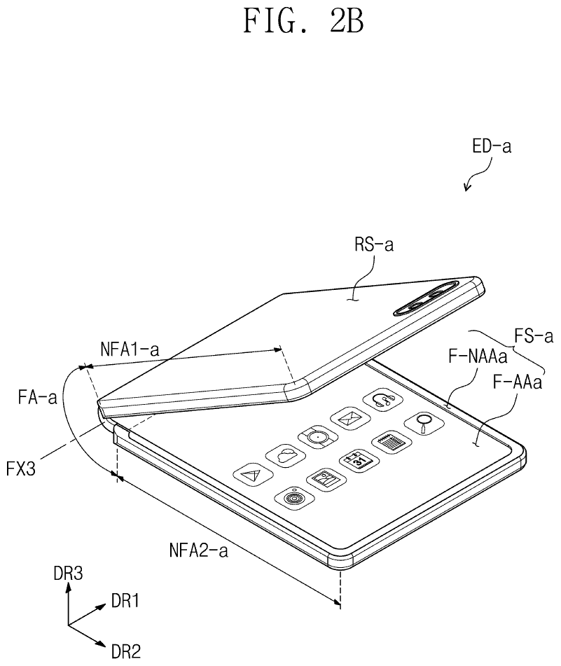

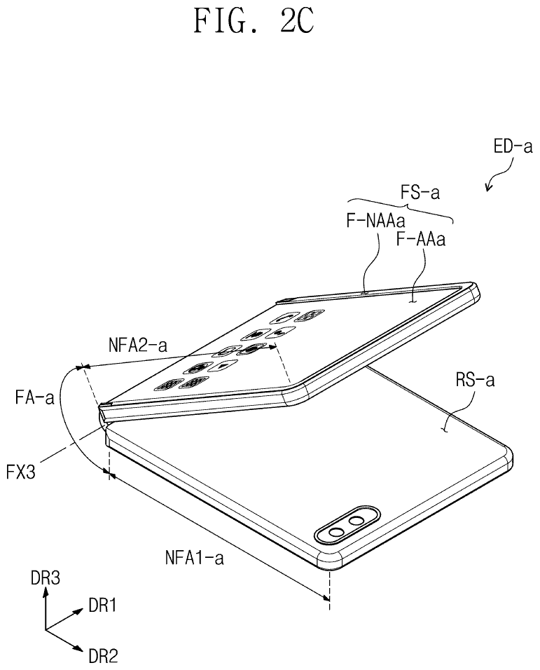

FIGS. 2A to 2C are perspective views illustrating an electronic device according to an embodiment.

FIG. 2A is a perspective view of an electronic device ED-a according to another embodiment of the invention. FIG. 2A is a perspective view illustrating the electronic device ED-a in an unfolded state. FIGS. 2B and 2C are perspective views illustrating a folding operation of the electronic device ED-a. FIG. 2B is a perspective view illustrating an in-folding operation of the electronic device ED-a illustrated in FIG. 2A. FIG. 2C is a perspective view illustrating an out-folding operation of the electronic device ED-a illustrated in FIG. 2A. FIG. 2B may be a view illustrating the electronic device ED-a in a first mode. FIG. 2C may be a view illustrating the electronic device ED-a in a second mode.

Referring to FIG. 2A, an embodiment of the electronic device ED-a may be folded with respect to a third folding axis FX3 extending along the first direction DR1. An extending direction of the third folding axis FX3 may be parallel to an extending direction of a short side of the electronic device ED-a.

The electronic device ED-a may be divided into a folding region FA-a, a first non-folding region NFA1-a adjacent to one side of the folding region FA-a, and a second non-folding region NFA2-a adjacent to the other side of the folding region FA-a. The first non-folding region NFA1-a and the second non-folding region NFA2-a may be spaced apart from each other with the folding region FA-a therebetween.

The folding region FA-a may be a region which is folded with respect to the third folding axis FX3. In a state in which the electronic device ED-a is folded, the folding region FA-a may have a predetermined curvature and a radius of a curvature. The electronic device ED-a may be in-folded such that the first non-folding region NFA1-a and the second non-folding region NFA2-a face each other and a display surface FS-a is not exposed to the outside.

According to an embodiment, in a state in which the electronic device ED-a is unfolded (that is, a state of not being folded), the display surface FS-a may be visible to a user. As described above with references to FIGS. 1A to 1D, the display surface FS-a of the electronic device ED-a may include an active region F-AAa and a peripheral region F-NAAa. The active region F-AAa may be a region in which the image IM may be displayed and various types of external inputs may be detected.

Referring to FIG. 2B, in a state in which the electronic apparatus ED-a according to an embodiment is in-folded, a rear surface RS-a may be visible to a user. In an embodiment, for example, the rear surface RS-a may function as a second display surface on which a video or image is displayed. Additionally, an electronic module region, in which an electronic module including various components is disposed, may be disposed also in the rear surface RS-a. According to an embodiment, the rear surface RS-a of the electronic device ED-a may further include an active region on which an image is displayed.

Referring to FIG. 2C, the electronic device ED-a may be folded with respect to the third folding axis FX3 and be changed into an out-folded state such that in the rear surface RS-a, one region overlapping the first non-folding region NFA1-a and the other region overlapping the second non-folding region NFA2-a face each other.

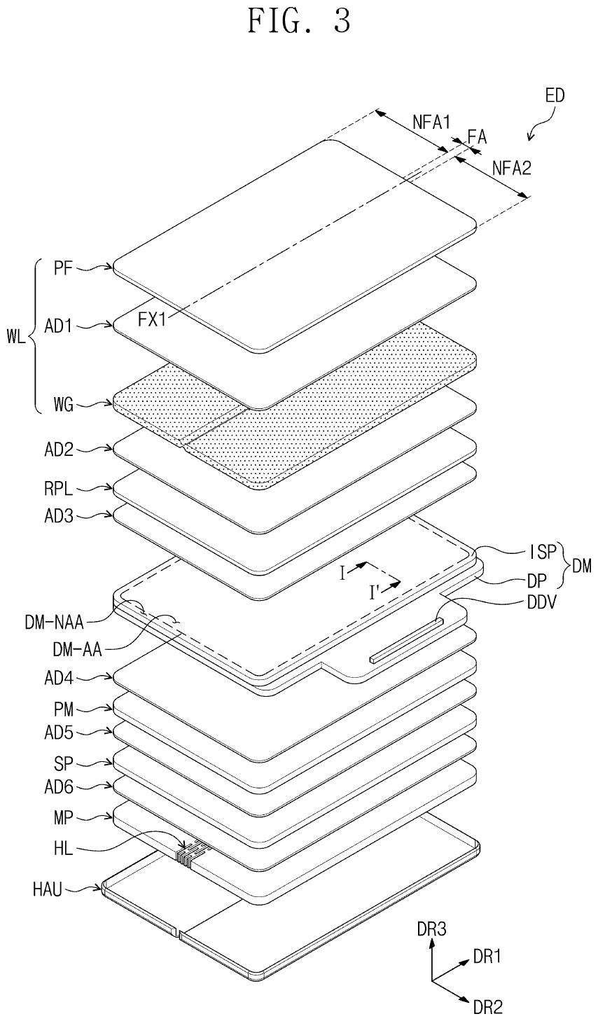

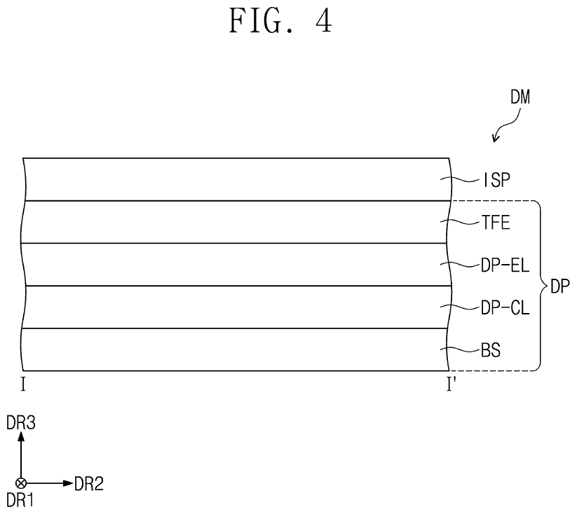

FIG. 3 is an exploded perspective view illustrating an electronic device according to an embodiment. FIG. 4 is a cross-sectional view taken along line I-I′ of FIG. 3. Hereinafter, features of an electronic device ED to be described below may be applied to the electronic device ED-a described with reference to FIGS. 2A to 2C.

Referring to FIG. 3, an embodiment of the electronic device ED may include a window WL, an optical layer RPL, a display module DM, a lower film PM, a support plate SP, a lower plate MP, and a housing HAU.

The housing HAU may be coupled to the window WL to define an exterior of the electronic device ED. The housing HAU may include a material having relatively high rigidity. In an embodiment, for example, the housing HA U may include a plurality of frames and/or support plates composed of glass, plastic, or metal. The housing HAU may provide a predetermined accommodation space. The display module DM may be accommodated inside the accommodation space and protected against an external impact. According to an embodiment, a hinge structure, etc., for guiding a folding operation of the electronic device ED may be further included in the housing HAU overlapping the folding region FA.

The display module DM may be disposed below the optical layer RPL. The display module DM may be activated in response to an electrical signal. The display module DM may be activated to display the image IM (see FIG. 1A) on the active region F-AA (see FIG. 1A) of the electronic device ED. A display region DM-AA and a non-display region DM-NAA may be defined in the display module DM. The display region DM-AA may be activated in response to an electrical signal. The non-display region DM-NAA may be a region which is located adjacent to at least one side of the display region DM-AA. A circuit, a line, etc., for driving the display region DM-AA may be disposed in the non-display region DM-NAA.

The optical layer RPL may be disposed between the display module DM and the window WL. The optical layer RPL may be an anti-reflective layer which reduces reflectance for external light incident from the outside of the display module DM. The optical layer RPL may be formed on the display module DM through a continuous process. The optical layer RPL may include a polarization plate or a color filter layer. In an embodiment, for example, the optical layer RPL may include at least one selected from a retarder, a polarizer, a polarization film, or a polarization filter. Alternatively, the optical layer RPL may include a plurality of color filters disposed in a predetermined arrangement, and a black matrix adjacent to the color filters.

The image IM (see FIG. 1A) generated from the display module DM may pass through the window WL and be provided to a user. The window WL may include a polymer substrate or a mother glass.

The window WL according to an embodiment may include a protective layer PF and a window glass WG. The protective layer PF and the window glass WG may include an optically transparent insulating material.

The protective layer PF may be disposed on the window glass WG. The protective layer PF may be a functional layer which protects an upper surface of the window glass WG. In an embodiment, for example, the protective layer PF may include a polymer film.

The window glass WG according to an embodiment of the invention may have a shape in which a portion of overlapping the folding region FA is etched in both directions, and a manufacturing method of the window glass WG described above will be described later.

The lower film PM may protect a lower part of the display panel DP. The lower film PM may include a flexible plastic material. In an embodiment, for example, the lower film PM may include polyethylene terephthalate.

The support plate SP may be disposed below a display panel DP. A portion of the support plate SP according to the invention may be bent to absorb an impact applied between the housing HAU and components disposed on the support plate SP. Additionally, the support plate SP may prevent foreign substances, etc., from being introduced into the components disposed on the support plate SP.

The lower plate MP may be disposed below the support plate SP. The lower plate MP may be provided with a plurality of holes HL overlapping the folding region and defined through the lower plate MP such that a folding operation of the electronic device ED is facilitated. The lower plate MP may include metal. In an embodiment, for example, the lower plate MP may include either of aluminum (Al) or molybdenum (Mo). However, an embodiment of the invention is not limited thereto, and the lower plate MP may include a matrix including fillers, and woven fiber lines disposed within the matrix. The fiber lines may be arranged in a fabric form within the matrix.

The fiber lines may include a reinforced fiber composite material. The reinforced fiber composite material may be either of a carbon fiber-reinforced plastic (CFRP) or a glass fiber-reinforced plastic (GFRP). One strand of fiber included in one fiber line may have a diameter of about 3 micrometers (μm) to about 10 μm.

The matrix according to an embodiment may include at least one selected from epoxy, polyester, polyamide, polycarbonate, polypropylene, polybutylene, or vinyl ester.

The matrix may include a filler. The filler may include at least one selected from silica, barium sulphate, sintered talc, barium titanate, titanium oxide, clay, alumina, mica, boehmite, zinc borate, or zinc stannate.

Although not illustrated, the electronic device ED according to an embodiment may further include either of a cushion layer or a shielding layer. The cushion layer may effectively prevent the lower plate MP from being dented and plastically deformed due to an external impact and force. The cushion layer may include an elastomer such as a sponge, a foam, or a urethane resin. Additionally, the cushion layer may include or be formed of at least one selected from an acryl-based polymer, a urethane-based polymer, a silicone-based polymer, or an imide-based polymer. The shielding layer may be an electromagnetic wave shielding layer or a heat dissipation layer.

The electronic device ED according to an embodiment may further include first to sixth adhesive layers AD1 to AD6. The first adhesive layer AD1 may be disposed between the window glass WG and the protective layer PF. The second adhesive layer AD2 may be disposed between the optical layer RPL and the window glass WG. The third adhesive layer AD3 may be disposed between the display module DM and the optical layer RPL. The fourth adhesive layer AD4 may be disposed between the lower film PM and the display module DM. The fifth adhesive layer AD5 may be disposed between the support plate SP and the lower film PM. The sixth adhesive layer AD6 may be disposed between the lower plate MP and the support plate SP.

The first to sixth adhesive layers AD1 to AD6, and the adhesive layers to be described later may each include a typical bonding agent such as a pressure sensitive adhesive (PSA), an optically clear adhesive (OCA), an optical clear resin (OCR), and are not limited to any one embodiment. In the electronic device ED according to an embodiment, at least one selected from the first to sixth adhesive layers AD1 to AD6 may be omitted.

FIG. 4 is a cross-sectional view, of a display module, illustrating a portion taken along line l-I′ of FIG. 3.

Referring to FIG. 4, the display module DM may include the display panel DP and the input-sensing layer ISP disposed on the display panel DP.

In an embodiment, the display panel DP may be configured to substantially generate an image. The display panel DP may be a light-emitting display panel. In an embodiment, for example, the display panel DP may be an organic light-emitting display panel, an inorganic light-emitting display panel, a micro light emitting diode (LED) display panel, a micro organic light emitting diode (OLED) display panel, or a nano LED display panel.

In an embodiment, the display panel DP may include a base layer BS, a circuit element layer DP-CL, a display element layer DP-EL, and an encapsulation layer TFE, which are sequentially stacked.

The base layer BS may provide a base surface on which the circuit element layer DP-CL is disposed. The base layer BS may be a flexible substrate which is bendable, foldable, rollable, etc. The base layer BS may be a mother glass, a metal substrate, a polymer substrate, etc. However, an embodiment of the invention is not limited thereto, and the base layer BS may include an inorganic layer, an organic layer, or a composite material layer.

The base layer BS may include a single layer or multi layers. In an embodiment, for example, the base layer BS may include a first synthetic resin layer, a multi-or single-layered inorganic layer, or a second synthetic resin layer disposed on the multi-or single-layered inorganic layer. The first synthetic resin layer and the second synthetic resin layer may each include a polyimide-based resin. Additionally, the first synthetic resin layer and the second synthetic resin layer may each include at least one selected from an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜based” resin is considered as including a functional group of “˜˜”.

The circuit element layer DP-CL may be disposed on the base layer BS. The circuit element layer DP-CL may include an insulating layer, a semiconductor pattern, a conductive pattern, a signal line, etc. The display element layer DP-EL may be disposed on the circuit element layer DP-CL. The display element layer DP-EL may include a light-emitting element (not illustrated). In an embodiment, for example, the light-emitting element may include an organic light-emitting material, an inorganic light-emitting material, an organic-inorganic light-emitting material, quantum dots, quantum rods, a micro LED, or a nano LED.

The encapsulation layer TFE may be disposed on the display element layer DP-EL. The encapsulation layer TFE may protect the display element layer DP-EL against moisture, oxygen, and foreign substances such as dust particles. The encapsulation layer TFE may include at least one inorganic layer. In an embodiment, for example, the encapsulation layer TFE may include an inorganic layer, an organic layer, and an inorganic layer which are sequentially stacked.

The input-sensing layer ISP may be disposed on the display panel DP. The input-sensing layer ISP may be directly disposed on the encapsulation layer TFE. Alternatively, an adhesive member may be disposed between the input-sensing layer ISP and the display panel DP.

In this specification, the wording, “an element is directly disposed on another element” means that there is no intervening element therebetween. That is, the wording, “an element is ‘directly disposed on’ another element” means that the element is “in contact with” the other element.

The input-sensing layer ISP may detect an external input, change the detected external input to a predetermined input signal, and provide the input signal to the display panel DP. In an embodiment, for example, the input-sensing layer ISP may be a touch-sensing layer which detects a touch. The input-sensing layer ISP may recognize a direct touch by a user, an indirect touch by a user, a direct touch by an object, or an indirect touch by an object.

The input-sensing layer ISP may detect either of a position or intensity (a pressure) of a touch applied from the outside. The input-sensing layer ISP may have various structures or be composed of various materials, but is not limited to any one embodiment. In an embodiment, for example, the input-sensing layer ISP may detect an external input in a capacitive manner. The display panel DP may receive input signals from the input-sensing layer ISP and generate images corresponding to the input signals.

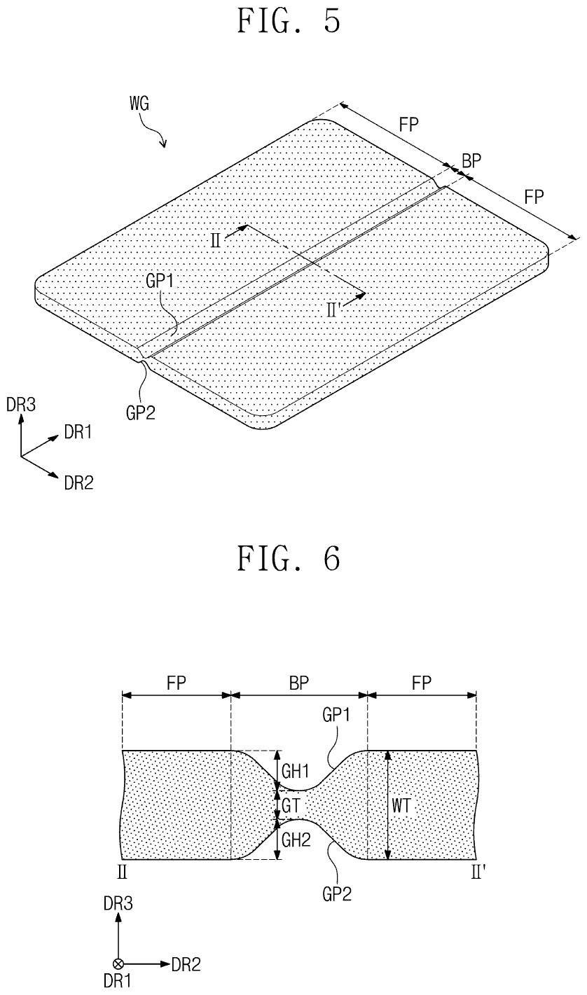

FIG. 5 is a perspective view illustrating a window glass manufactured through a manufacturing method of a window glass according to an embodiment. FIG. 6 is a cross-sectional view, of a window glass, illustrating a portion taken along line ll-II′ of FIG. 5.

Referring to FIGS. 5 and 6 together, a window glass WG according to an embodiment may include a bending region BP and a flat region FP. The bending region BP and the flat region FP may be regions respectively corresponding to the folding region FA and the non-folding regions NFA1 and NFA2, which are described with reference to FIG. 3.

Groove patterns GP1 and GP2 may be defined in the bending region BP of the window glass WG. The groove patterns GP1 and GP2 may include an upper groove GP1 defined on an upper surface of the window glass WG, and a lower groove GP2 defined on a lower surface of the window glass WG. The upper groove GP1 and the lower groove GP2 may overlap each other on a plane or in the third direction DR3.

A depth of the upper groove GP1 may be defined as an upper depth GH1, and a depth of the lower groove GP2 may be defined as a lower depth GH2. In an embodiment, the upper depth GH1 may be defined as a maximum depth with respect to a flat surface extending from the upper surface of the window glass WG on which the upper groove GP1 is not defined, and the lower depth GH2 may be defined as a maximum depth with respect to a flat surface extending from the lower surface of the window glass WG on which the lower groove GP2 is not defined.

As will be described later, since forming processes of the upper groove GP1 and the lower groove GP2 are simultaneously performed, the upper depth GH1 may be substantially the same as the lower depth GH2. In an embodiment, for example, a ratio of the upper depth GH1 to the lower depth GH2 may be in a range of about 0.95 to about 1.05.

A minimum thickness of the window glass WG in the bending region BP may be defined as a bending thickness GT, and a thickness of the window glass WG in the flat region FP may be defined as a flat thickness WT.

The sum of the upper depth GH1, the bending thickness GT, and the lower depth GH2 may be the same as the flat thickness WT.

Since the groove patterns GP1 and GP2 are defined or formed in the bending region BP, the bending thickness GT may be smaller than the flat thickness WT. In an embodiment, the bending thickness GT may be in a range of about 30 μm to about 100 μm. The flat thickness WT may be in a range of about 30 μm to about 1000 μm. In an embodiment where the flat thickness WT is in a range of about 100 μm or less, the bending thickness may be about 30 μm or greater and less than the flat thickness WT.

The bending thickness GT of the window glass WG according to this embodiment is smaller than the flat thickness WT, and thus the window glass WG may have improved bending characteristics in the bending region BP.

In the case in which a typical window glass has a groove pattern etched only in “one direction”, it is desired to deeply form one groove pattern to form a small bending thickness, which may cause cracks in the window glass.

In an embodiment of the invention, since the window glass WG has a shape etched in “both directions”, it is possible to form the small bending thickness GT even when the depths GH1 and GH2 of the groove patterns are each shallowly formed.

Additionally, since the bending thickness GT is determined by two factors of the upper depth GH1 and the lower depth GH2, the risk of tolerance occurrence may be reduced than that in a case where the bending thickness is determined by one factor.

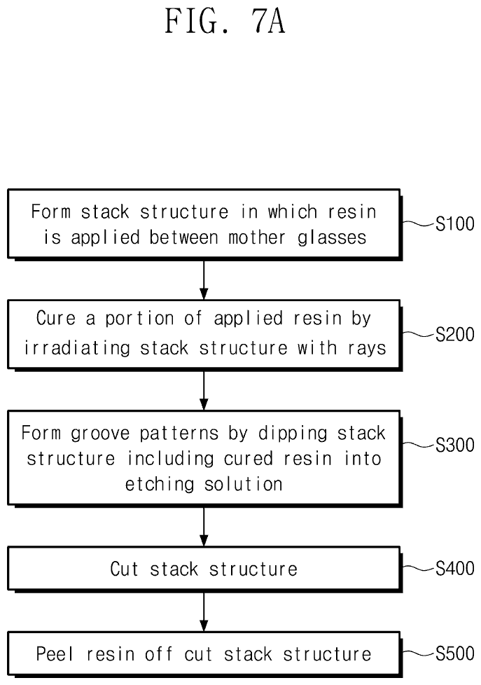

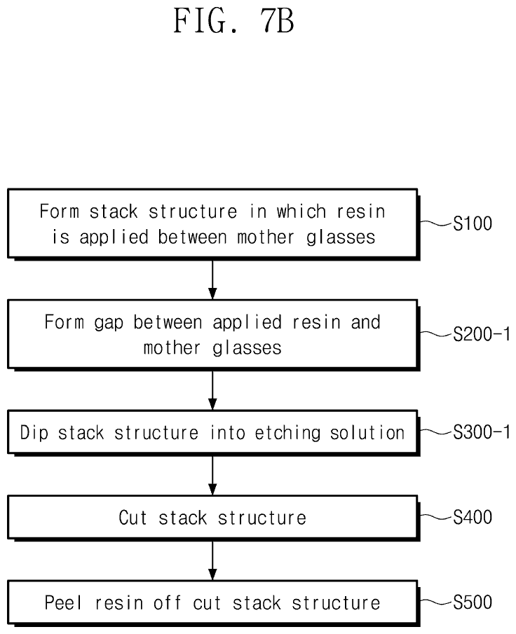

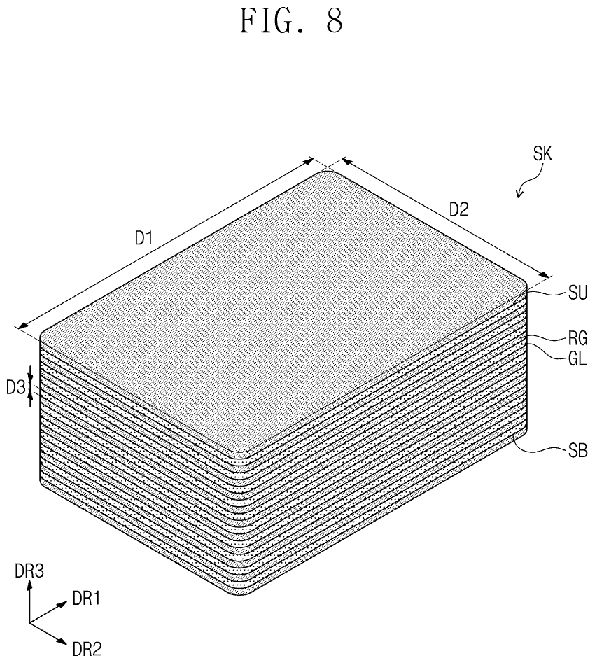

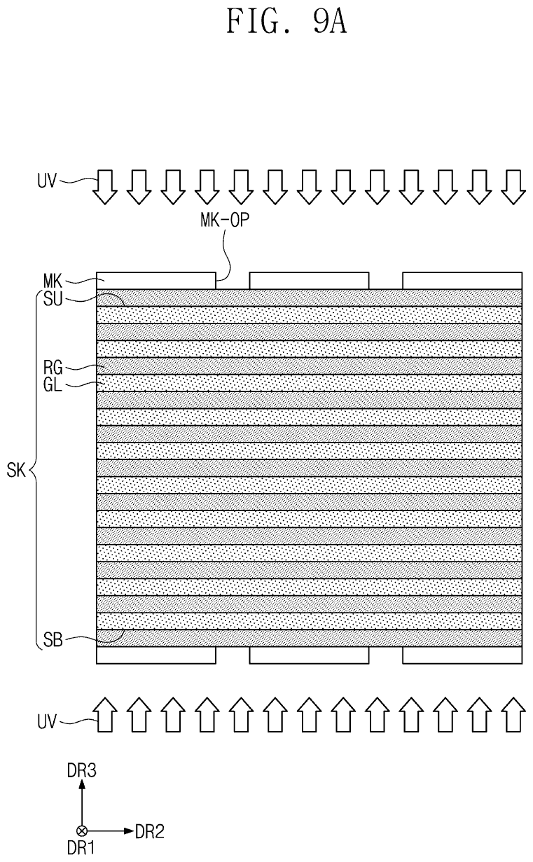

FIG. 7A is a block diagram showing a manufacturing method of a window glass according to an embodiment.

The manufacturing method of the window glass according to an embodiment of the invention may include processes of: forming a stack structure in which a resin is applied between mother glasses (S100); curing a portion of the applied resin by irradiating the stack structure with rays (S200); forming groove patterns on the mother glasses by dipping the stack structure including the cured resin into an etching solution (S300); and cutting the stack structure (S400).

The manufacturing method of the window glass according to an embodiment of the invention may further include a process of removing the resin from the cut stack structure, e.g., peeling the resin off the cut stack structure (S500).

FIG. 7B is a block diagram showing a manufacturing method of a window glass according to an embodiment.

The manufacturing method of the window glass according to an embodiment of the invention may include processes of: forming a stack structure in which a resin is applied between mother glasses (S100); forming a gap between the applied resin and the mother glasses by disposing a mask on one surface of the stack structure and irradiating the mask with rays (S200-1); dipping the stack structure into an etching solution (S300-1); and cutting the stack structure (S400). The manufacturing method of the window glass according to an embodiment of the invention may further include the process of removing the resin from the cut stack structure, e.g., peeling the resin off from the cut stack structure (S500).

FIGS. 8 to 12 are views illustrating each step in a manufacturing method of a window glass according to an embodiment of the invention.

Hereinafter, the manufacturing method of the window glass according to an embodiment will be described with reference to FIGS. 8 to 12.

A stack structure SK illustrated in FIG. 8 may be manufactured through the process of forming a stack structure (S100). FIG. 8 illustrates a single stack structure SK as an example, and a shape and configuration of the stack structure SK will be described below with reference to FIG. 8.

The stack structure SK may include mother glasses GL, and a resin RG applied between the mother glasses GL. In an embodiment, the resin RG may be further applied on an upper surface SU of the mother glass GL located on an uppermost part and a lower surface SB of the mother glass GL located on a lowermost part, among the mother glasses GL included in the stack structure SK. In such an embodiment, the upper groove GP1 (see FIG. 5) and the lower groove GP2 (see FIG. 5) may also be formed on each of the upper surface SU of the mother glass GL located on the uppermost part and the lower surface SB of the mother glass GL located on the lowermost part, among the mother glasses GL included in the stack structure SK.

The mother glasses GL may each correspond to a “glass substrate” used for finally manufacturing the window glass WG (see FIG. 5). The window glass WG (see FIG. 5) may correspond to ultra thin glass (UTG). Accordingly, the mother glasses GL for manufacturing the window glass WG may also have extremely small thicknesses. In an embodiment, the mother glasses GL may each have a thickness D3 of about 30 μm to about 1000 μm.

On a plane or when viewed in the third direction DR3, the area of each of the mother glasses GL may be greater than the area of the window glass WG (see FIG. 5). The mother glasses GL may have sufficient areas on a plane such that a plurality of sheets of the window glass WG (see FIG. 5) are manufactured by cutting one stack structure SK. In an embodiment, on a plane, the mother glasses GL may each have a rectangular shape in which a length of one side D1 is in a range of about 300 mm to about 1000 mm, a length of the other side D2 is in a range of about 200 mm or more, and a length in one direction is in a range of about 200 mm to about 700 mm.

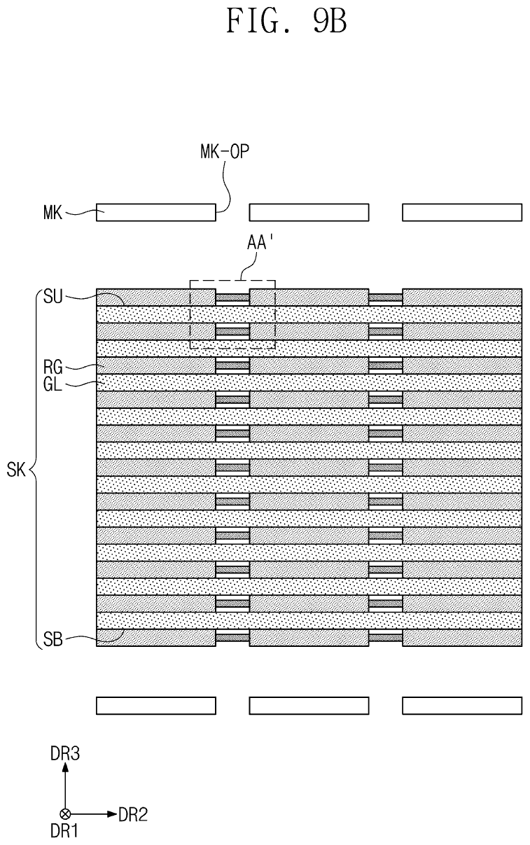

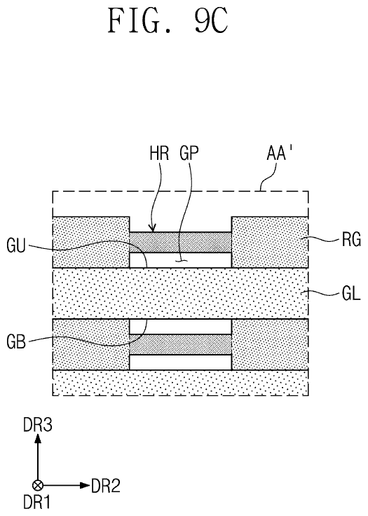

FIG. 8 illustrates an embodiment where the stack structure SK includes about 10 sheets of the mother glass GL as an example. However, the number of the mother glasses GL included in the stack structure SK is not limited to what is illustrated in the drawings. The stack structure SK according to an embodiment of the invention includes a plurality of sheets of the mother glass GL to manufacture a plurality of sheets of the window glass WG (see FIG. 5) through a single process. However, if an excessive number of the mother glasses GL are provided, in the process of curing a portion of the later-described resin (S300) (see FIG. 7A), a sufficient amount of rays UV (see FIG. 9A) may not reach up to the resin RG located in an inner side of the stack structure SK. Accordingly, the stack structure SK according to an embodiment may include about 2 sheets to about 30 sheets of the mother glass GL (i.e., the number of the mother glasses GL in the stack structure SK is greater than or equal to 2 and less than or equal to 30) such that the resin RG is effectively prevented from being uncured as well as process efficiencies are achieved.

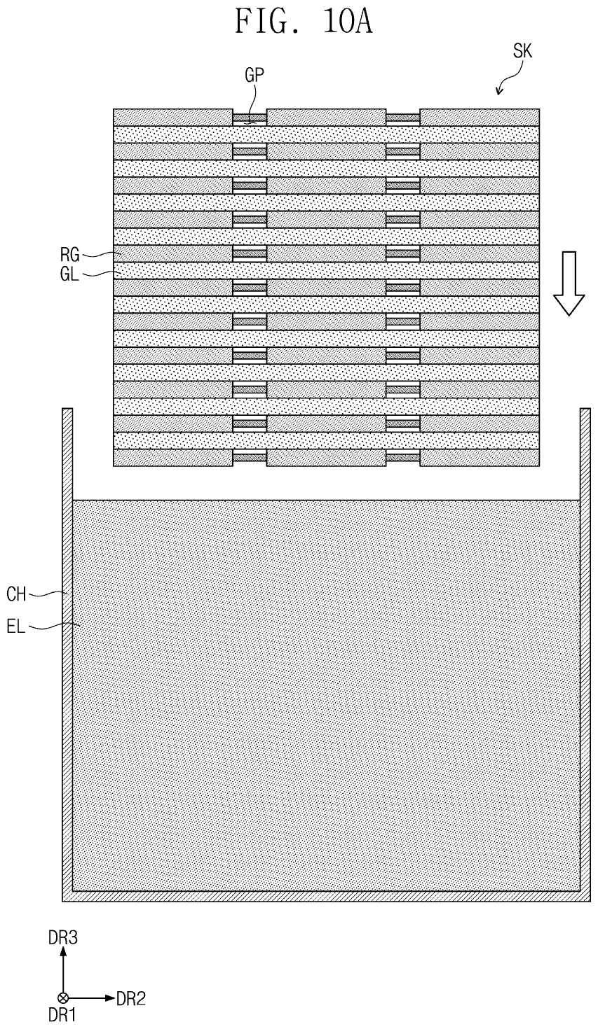

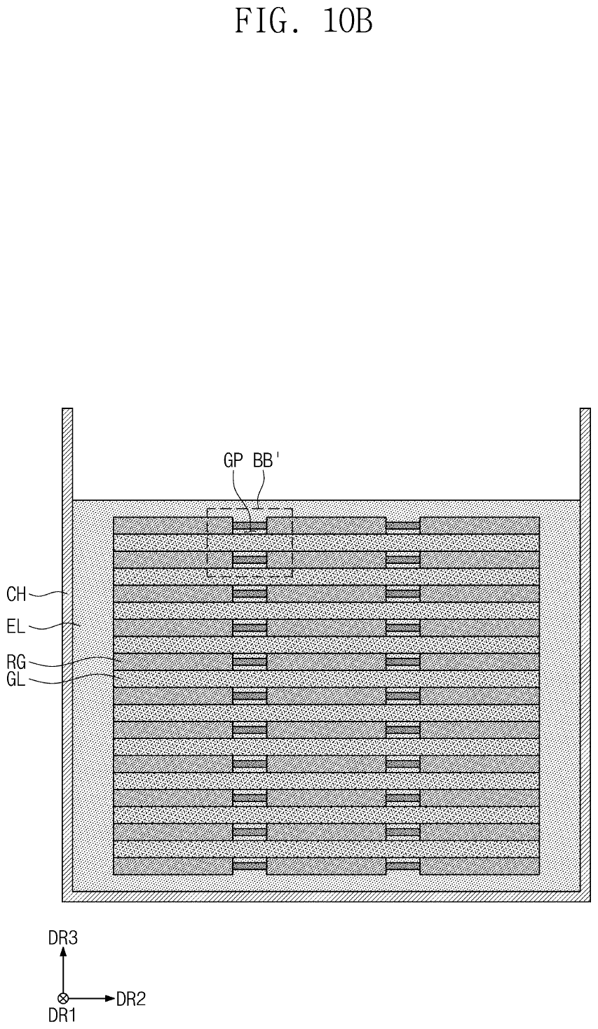

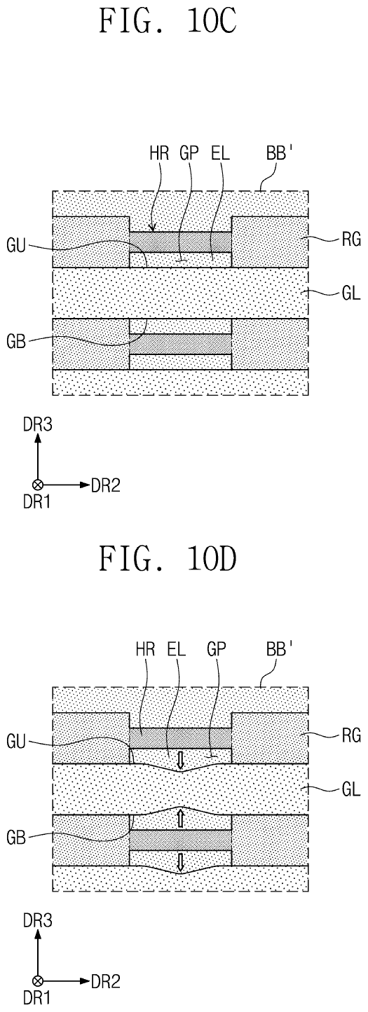

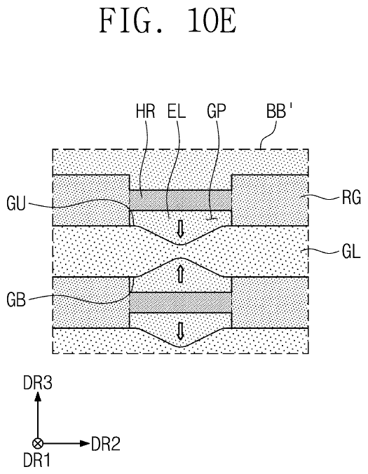

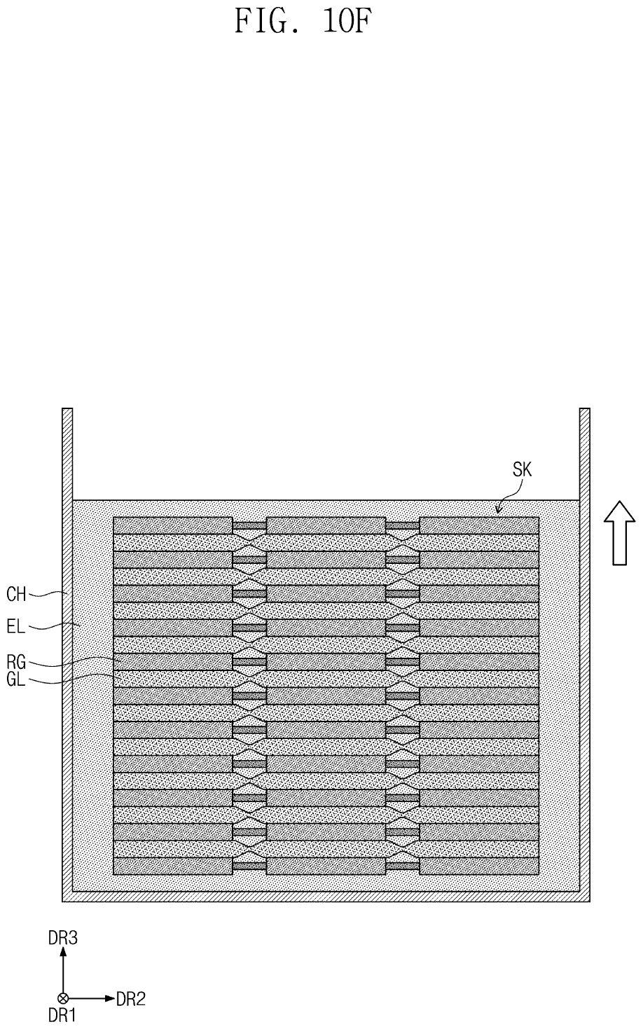

The resin RG may be applied on an upper surface and a lower surface of each of the mother glasses GL. The resin RG may be fully applied to prevent void spaces from being formed between the mother glasses GL. In this manner, only a portion selected from the fully applied resin RG is cured, so that a “gap GP (see FIG. 9C)” may be provided to serve as a path through which an etching solution EL (see FIG. 10A) flows into. This will be described later.

The resin RG may include a photosensitive material. In an embodiment, for example, the resin RG may include at least one selected from an epoxy-based polymer, an acryl-based polymer, polyisoprene, polyimide, polysulfone, a monomer, an oligomer, etc. The resin RG may further include a photoinitiator for promotion of photocuring. Accordingly, in the resin RG, a portion exposed to rays UV (see FIG. 9C) has curability. This will be described later.

FIGS. 9A to 9C are views illustrating the process of curing a portion of the resin (S200) or the process of forming a gap (S200-1).

Referring to FIG. 9A, the process of curing a portion of the resin (S200) may include processes of: disposing a mask MK having a mask pattern MK-OP formed therein on one surface of a stack structure SK, and irradiating the mask MK with the rays UV.

The mask MK according to an embodiment may have a mask pattern MK-OP defined therein. In this specification, the mask pattern MK-OP may be referred to as an “opening”. The opening MK-OP of the mask MK may be defined or formed through the mask MK to extend from an upper surface to a lower surface of the mask MK in the third direction DR3.

In the mask MK, a portion in which the opening MK-OP is not defined blocks the rays UV, and a portion in which the opening MK-OP is defined transmits the rays UV, and thus it is possible to cure only some portions of the resin RG applied to the stack structure SK.

FIG. 9A illustrates an embodiment where the masks MK each is provided with two openings MK-OP defined therein as an example. However, an embodiment of the invention is not limited to what is illustrated in the drawings, and the number, a location, a shape, etc. of the opening MK-OP may be designed to correspond to the number, locations, shapes, etc. of the groove patterns GP1 and GP2 (see FIG. 5) to be formed.

FIG. 9A illustrates an embodiment where the mask MK is disposed on each of both an upper surface and a lower surface of the stack structure SK as an example. However, an embodiment of the invention is not limited thereto. In another embodiment, for example, the mask MK may be only disposed on either of the upper surface or the lower surface of the stack structure SK.

The rays UV may function to cure a portion of the resin RG included in the stack structure SK. The rays UV may be emitted toward the mask MK, and some of the emitted rays UV may pass through the opening MK-OP to reach the resin RG. The rays UV may correspond to ultraviolet rays.

Hereinafter, referring to FIGS. 9B and 9C together, a portion of the resin RG irradiated with the rays UV is cured, such that a “cured resin HR” may be formed. Since the cured resin HR is formed through solidification of the resin RG, the cured resin HR may have a relatively smaller volume (e.g., a thinner thickness) than the resin RG.

A “gap GP”, corresponding to a reduced volume of the resin RG due to curing, may be formed between the cured resin HR and a mother glass GL. The gap GP may be defined as a space between the cured resin HR and the mother glass GL. As will be described later, the gap GP may serve as a path through which an etching solution EL (see FIG. 10A) flows into the stack structure SK. In this specification, the gap GP may be referred to as a “void space” between the cured resin HR and the mother glass GL.

FIG. 9C illustrates an embodiment on a cross section, surfaces of the mother glass GL, the resin RG, and the cured resin HR define the gap GP and have a quadrilateral shape. However, a shape of the gap GP is not limited to what is illustrated in the drawing as long as a path through the etching solution EL (see FIG. 10A) flows into may be provided.

FIGS. 10A to 10F are views illustrating the process of forming groove patterns (S300).

The process of forming groove patterns (S300) may include processes of: dipping a stack structure SK having a gap GP formed therein into the etching solution EL (see FIG. 7B) (S300-1); reacting mother glasses GL with the etching solution EL; and retrieving the stack structure SK from the etching solution EL.

Referring to FIG. 10A, the process of dipping the stack structure SK into the etching solution EL may include a process of disposing the stack structure SK inside a chamber CH, in which the etching solution EL is contained, by lowering the stack structure SK in the third direction DR3.

The etching solution EL corresponds to a solution by which a glass material is chemically etched. In an embodiment, for example, the etching solution EL may include hydrofluoric acid. However, the etching solution EL is not limited thereto, and may further include nitric acid, sulfuric acid, etc.

Next, referring to FIGS. 10B to 10E, the process of reacting the mother glasses GL with the etching solution EL may be performed.

Since the chamber CH may have a sufficient inner space capable of accommodating the stack structure SK, the entire stack structure SK may be immersed in the etching solution EL.

FIGS. 10C to 10E are enlarged views of region BB′ of FIG. 10B. FIGS. 10C to 10E may be views time-serially illustrating the reaction of the mother glass GL with the etching solution EL. An etching process of the mother glass GL by using the etching solution EL may correspond to a slimming etching process.

Referring to FIGS. 10C to 10E together, the etching solution EL may flow into the stack structure SK via the gap GP. The etching solution EL flowing into the stack structure SK via the gap GP may be in contact with an upper surface GU and a lower surface GB of the mother glass GL to etch the mother glasses GL. The upper surface GU and the lower surface GB of each of the mother glasses GL may be simultaneously etched. The mother glasses GL may each be etched by the etching solution EL in both directions. The mother glasses GL may each be etched by the etching solution EL in both directions opposite to each other.

The upper surface GU of the mother glass GL may be etched to form an upper groove GP1 (see FIG. 6), and the lower surface GB of the mother glass GL may be etched so as to form a lower groove GP2.

A speed at which the mother glass GL is etched by the etching solution EL may be in a range of about 0.2 micrometer per minute (μm/min) to about 5 μm/min, which may be determined on the basis of a depth by which the mother glass GL is etched.

The upper depth GH1 (see FIG. 6) and the lower depth GH2 (see FIG. 6) may be controlled by adjusting a time for which the mother glass GL is immersed in the etching solution EL.

Thereafter, as illustrated in FIG. 10F, the process of retrieving the stack structure SK from the etching solution EL may be performed. The process of retrieving the stack structure SK may be performed by raising the stack structure SK in the third direction DR3.

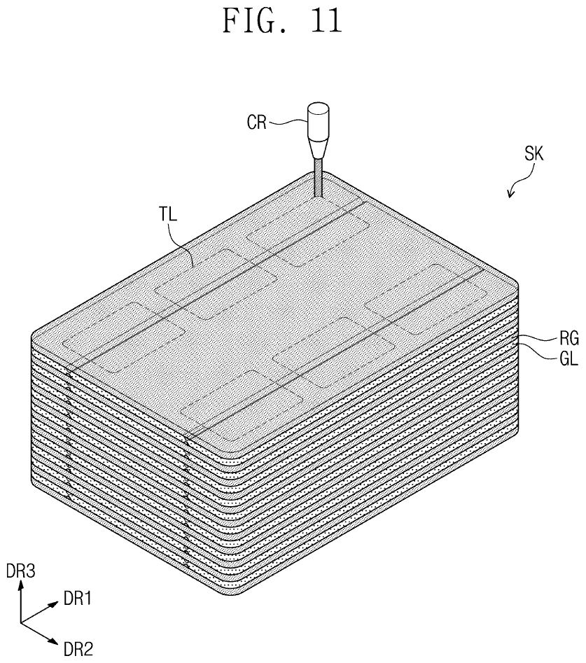

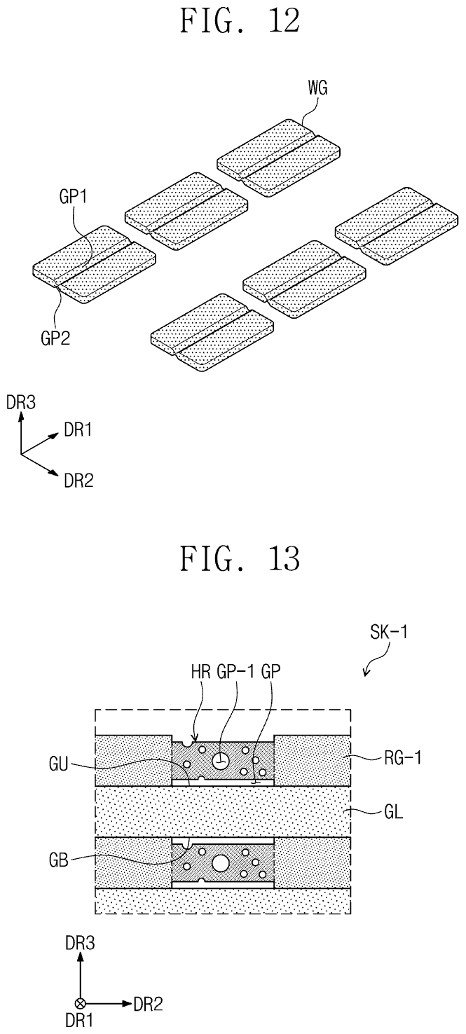

FIG. 11 is a perspective view illustrating the process of cutting the stack structure according to an embodiment (S400). FIG. 12 is a perspective view illustrating window glasses manufactured after the process of peeling the resin off the cut stack structure.

Referring to FIG. 11, the process of cutting the stack structure (S400) may include a process of cutting the stack structure SK along a cutting line TL corresponding to a shape of the window glass WG (see FIG. 12).

FIG. 11 illustrates an embodiment where a computer numerical control (CNC) carving machine CR cuts the stack structure SK while moving along the cutting Line TL. However, a method of cutting the stack structure SK is not particularly limited, and the stack structure SK may be cut through laser cutting, etc.

A plurality of sheets of the window glass WG may be formed by peeling the resin off the cut stack structure SK, and FIG. 12 illustrates an embodiment where about 6 sheets of the window glass WG are formed from one mother glass GL (see FIG. 11).

FIG. 13 is an enlarged view of a part of a stack structure formed through a manufacturing method of a window glass according to another embodiment of the invention. FIG. 13 is an enlarged view illustrating a portion of a stack structure SK-1 obtained immediately after the process of curing a portion of the resin (see FIG. 7A) (S200) is performed.

A resin RG-1 according to an embodiment may be cured by the rays UV (see FIG. 9A) and have a gap GP-1 formed therein. The gap GP-1 according to an embodiment may be formed to have an irregular pore shape. The etching solution EL (see FIG. 10A) may flow into the stack structure SK-1 via the gap GP-1 to etch the mother glass GL.

In such an embodiment, when the resin RG-1 is not sufficiently cured, since the gap GP-1 has an extremely small diameter, the etching solution EL (see FIG. 10A) may insufficiently flow into. When the resin RG-1 is excessively cured, since the gap GP-1 has an extremely great diameter, the etching solution EL (see FIG. 10A) may be excessively infiltrated.

Table 1 below shows results obtained from evaluating an infiltration amount according to diameters of the gaps GP-1 and energies of the rays UV (see FIG. 9A). The etching solution EL (see FIG. 10A) used for evaluation results may be at a temperature in a range of about 20 degrees Celsius to about 80 degrees Celsius.

TABLE 1

| | Energy of | | Infiltration of |
|---|---|---|---|
| Example | Ray (mJ) | Average Diameter of Gap | Etching Solution |
| 1 | 15000 | less than 20 μm | Unable |
| 2 | 18000 | 20 μm or more and less than | Partially |
| | | 500 μm | infiltrated |
| 3 | 21000 | 500 μm or more and less than | Able to |
| | | 1000 μm | infiltrate |
| 4 | 24000 | Greater than 1000 μm and less | Able to |
| | | than 2000 μm | infiltrate |
| 5 | 27000 | 2000 μm or more and less | Excessively |
| | | than 3000 μm | infiltrated |

Referring to Example 5 of the above-described Table 1, it may be confirmed that when an average diameter of the gaps GP-1 is about 2000 μm or greater, the etching solution is excessively infiltrated. Referring to Example 1 of Table 1, it may be seen that when an average diameter of the gaps GP-1 is in a range of about 20 μm or greater and less than about 2000 μm, the etching solution is infiltrated. Accordingly, in an embodiment, the gap GP-1 may have a diameter of about 100 μm or greater and less than about 2000 μm, such that an appropriate amount of the etching solution EL may be infiltrated.

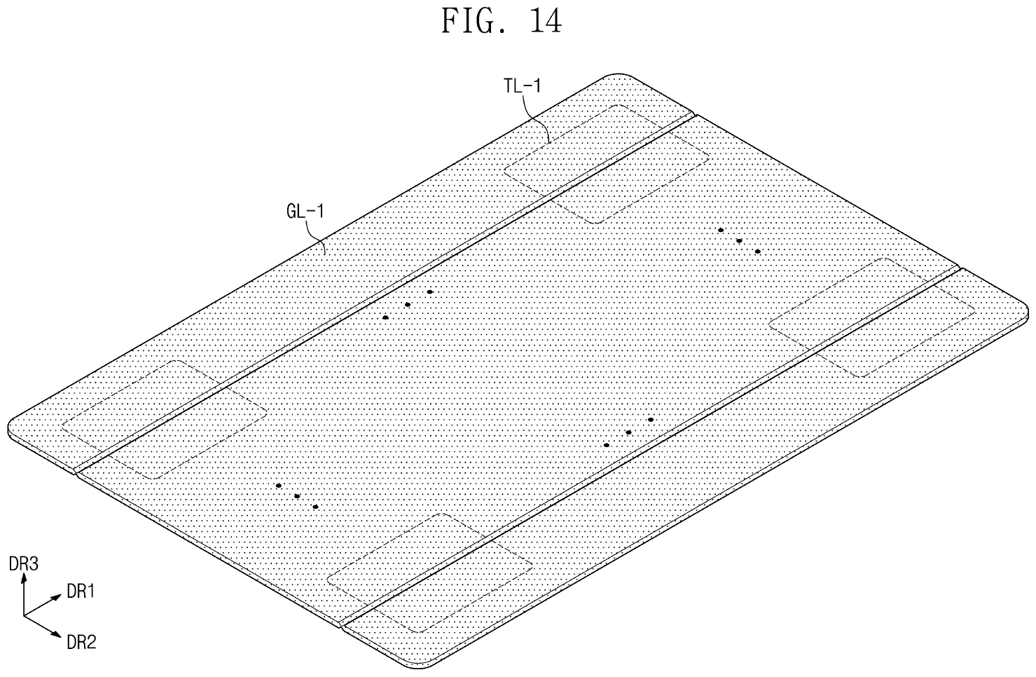

FIG. 14 is a perspective view illustrating a mother glass GL-1 manufactured according to another embodiment of the invention.

A plurality of sheets of a window glass WG may be manufactured from one mother glass GL-1 by controlling a planar size of the mother glass GL-1 and a planar size of a cutting line TL-1. In an embodiment, for example, when about 6 cutting lines TL-1 are arranged in the first direction DR1 and about 5 groove patterns GP1 and GP2 (see FIG. 6) are formed in the second direction DR2, about 30 sheets of the window glass WG may be manufactured from one mother glass GL-1.

That is, about 6 sheets to about 30 sheets of the window glass WG may be manufactured from one mother glass through the manufacturing method of the window glass according to an embodiment of the invention. In an embodiment, for example, when one stack structure SK includes about 30 sheets of the mother glass GL, a maximum of about 900 sheets of the window glass WG may be manufactured by once performing the manufacturing method of the window glass according to the invention. Therefore, the cost and time for the process of the mother glass GL may be significantly reduced than that of the individual process of the mother glass GL.

According to an embodiment of the invention, a manufacturing method of a window glass may allow a plurality of sheets of a window glass to be simultaneously manufactured during processes of producing a window glass used for a foldable electronic device.

Accordingly, the cost and time for manufacturing a window glass may be reduced, and the window glass with an improved folding characteristic may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A manufacturing method of a window glass, the manufacturing method comprising:
forming a stack structure in which a resin is applied between mother glasses;
curing a portion of the applied resin by irradiating the stack structure with rays;
forming groove patterns on the mother glasses by dipping the stack structure including the cured resin into an etching solution; and
cutting the stack structure.

2. The manufacturing method of claim 1, wherein the forming the groove patterns comprises:
forming an upper groove by etching an upper surface of each of the mother glasses; and
forming a lower groove by etching a lower surface of each of the mother glasses,
wherein the forming the upper groove and the forming the lower groove are simultaneously performed.

3. The manufacturing method of claim 1, wherein the resin comprises a photosensitive material,
the rays comprise ultraviolet rays, and
the forming the stack structure comprises applying a resin on an upper surface of a mother glass disposed on an uppermost part in the stack structure and a lower surface of a mother glass disposed on a lowermost part in the stack structure.

4. The manufacturing method of claim 1, wherein an upper groove and a lower groove are defined in each of the mother glasses on which the forming the groove patterns is performed, and
the upper groove overlaps the lower groove in a plan view.

5. The manufacturing method of claim 4, wherein a ratio of a depth of the upper groove to a depth of the lower groove is in a range of about 0.95 to about 1.05 in each of the mother glasses.

6. The manufacturing method of claim 4, wherein a sum of a depth of the upper groove, a depth of the lower groove, and a thickness of a mother glass overlapping the groove patterns is the same as a maximum thickness of the mother glass.

7. The manufacturing method of claim 1, wherein a thickness of a portion of a mother glass overlapping the groove patterns is smaller than a thickness of another portion of the mother glass not overlapping the groove patterns.

8. The manufacturing method of claim 1, wherein the curing the portion of the resin comprises disposing a mask provided with a mask pattern defined therein on at least one surface of the stack structure, and irradiating the mask with rays.

9. The manufacturing method of claim 1, wherein a number of the mother glasses in the stack structure is greater than or equal to 2 and less than or equal to 30.

10. The manufacturing method of claim 1, wherein before the forming the groove patterns, the mother glasses each have a thickness of about 30 μm to about 1000 μm,
after the forming the groove patterns, a portion of each of the mother glasses overlapping the groove patterns each have a thickness of about 30 μm to about 100 μm, and
a thickness of the portion of each of the mother glasses overlapping the groove patterns is smaller than a thickness of another portion of each of the mother glasses not overlapping the groove patterns.

11. The manufacturing method of claim 1, wherein the mother glass has a rectangular shape having a horizontal length of 200 mm to 700 mm and a vertical length of 300 mm to 1000 mm in a plan view.

12. The manufacturing method of claim 1, wherein a portion of the cured resin has a reduced volume, such that a gap is formed between the portion of the cured resin and the mother glass, and
in the forming the groove patterns, the etching solution flows into the stack structure via the gap.

13. The manufacturing method of claim 1, wherein the forming the groove patterns comprises performing slimming etching.

14. The manufacturing method of claim 1, wherein in the forming the groove patterns, a speed of etching the mother glass is equal or greater than about 0.2 μm/min to equal or less than about 5 μm/min.

15. The manufacturing method of claim 1, further comprising:
removing the resin from the cut stack structure,
wherein 6 sheets to 30 sheets of a window glass are formed from each of the mother glasses.

16. A manufacturing method of a window glass, the manufacturing method comprising:
forming a stack structure in which a resin is applied between mother glasses;
forming a gap between the applied resin and the mother glasses by disposing a mask on one surface of the stack structure and irradiating the mask with rays;
dipping the stack structure into an etching solution; and
cutting the stack structure.

17. The manufacturing method of claim 16, wherein the resin comprises a photosensitive material, and
the rays comprise ultraviolet rays.

18. The manufacturing method of claim 16, wherein the dipping the stack structure into the etching solution comprises:
allowing the etching solution to flow into the stack structure via the gap; and
etching the mother glasses with the etching solution flowing into the stack structure.

19. The manufacturing method of claim 18, wherein the etching the mother glasses comprises:
etching an upper surface of each of the mother glasses; and
etching a lower surface of each of the mother glasses, and
the etching the upper surface of each of the mother glasses and the etching the lower surface each of the mother glasses are simultaneously performed,
wherein a number of the mother glasses in the stack structure is greater than or equal to 2 and less than or equal to 30.

20. A manufacturing method of an electronic device comprising a display panel comprising pixels, a housing disposed under the display panel, and a window glass disposed on the display panel, the manufacturing method comprising:
forming a stack structure in which a resin is applied between mother glasses;
curing a portion of the applied resin by irradiating the stack structure with rays;
forming groove patterns on the mother glasses by dipping the stack structure including the cured resin into an etching solution; and
cutting the stack structure.
